(19) United States
(12) Patent Application Publication
(10) Pub. No.: US 2015/0372173 A1
(43) Pub. Date: Dec. 24, 2015

(54) GRADED TRANSPARENT CONDUCTING OXIDE (G-TCO) FOR THIN FILM SOLAR CELLS

(71) Applicant: UNIVERSITY OF FLORIDA RESEARCH FOUNDATION, INC., GAINESVILLE, FL (US)

(72) Inventors: ALBERT B. HICKS, GAINESVILLE, FL (US); TIMOTHY J. ANDERSON, AMHERST, MA (US)

(21) Appl. No.: 14/745,787

(22) Filed: Jun. 22, 2015

Related U.S. Application Data
(60) Provisional application No. 62/016,204, filed on Jun. 24, 2014.

(51) Int. Cl. H01L 31/0224; H01L 31/032; H01L 31/18; H01L 31/0445

(52) U.S. Cl. CPC H01L 31/022466; H01L 31/0445; H01L 31/0322; H01L 31/1884

(57) ABSTRACT

A graded transparent conducting oxide (G-TCO) electrode allows the thickness of the electrode to vary from a very thin distal end to a relatively thick proximal end that resides near a metal current collector, generally for a grid of an ensemble of photovoltaic cells such that the thickness increases with the current carrying requirement of the electrode and the optical losses by the electrode are minimized. In this manner a photovoltaic cell can be improved in efficiency by the minimization of the optical losses while assuring the electrode can support all photogenerated current. The G-TCO electrode is prepared by sputtering through a mask that is suspended above a substrate, such as a photovoltaic cell absent its top electrode, where the mask does not reside on the substrate, but is suspended above the substrate.

### CROSS-REFERENCE TO A RELATED APPLICATION

This application claims the benefit of U.S. Provisional Application Ser. No. 62/016,204, filed Jun. 24, 2014, the disclosure of which is hereby incorporated by reference in its entirety, including all figures, tables and drawings.

This invention was made with government support under DE-AC36-08G028308 awarded by the U.S. Department of Energy. The government has certain rights in the invention.

### BACKGROUND OF INVENTION

Current commercially available solar cell technology is dominated by silicon based solar cells. A technology alternative to silicon is based on thin-film absorbers, where a direct bandgap semiconductor is employed, where the light is completely adsorbed by a layer that is approximately 1/1000^{th} of the thickness of silicon solar cells. The most available thin film solar cell uses the semiconductor cadmium telluride, and panels are only a few percent less efficient than those of polycrystalline silicon. A thin film alternative to CdTe is copper indium gallium diselenide (CIGS), which, in addition to avoiding toxic cadmium, displays the highest thin film efficiency.

A traditional CIGS device structure is shown in FIG. 1. It includes a thin buffer layer of CdS, but this is a very small portion of the materials used in the overall device, when compared to a CdTe device, and furthermore progress should result in a cadmium-free CIGS cell. CIGS is an extremely stable solar compound and has an optical absorption coefficient that is sufficiently high that device thickness can be less than 2 μm.

The typical CIGS device has a substrate with a smooth surface and a high chemical stability for supporting razor-thin layers of semiconductor. Typical substrates for commercially available models are glass and steel foil. Typically, a molybdenum layer serves as a back electrical contact that promotes a firm bond for other layers and supports a CIGS absorber layer. The CIGS bandgap can be tuned by the indium and gallium ratio, allowing a bandgap of 1.1 eV to about 1.4 eV. The CIGS absorber layer is fabricated with a gradient of high gallium on the back side to promote photogenerated electrons for collection deep in the structure. Upon the CIGS absorber layer is the CdS buffer layer. CdS is a p-type semiconductor that forms a pn junction with the CIGS layer. A secondary junction is formed by the exchange of copper and cadmium ions, which creates a thin layer of electrically inverted (n-type) CIGS. The role of the inversion layer is not well understood, but is observed to be beneficial, while a thick layer promotes interfacial recombination. The thickness of this layer depends on the heat to which the device is exposed after the CdS layer is deposited, and temperature above 100° C. is best to be avoided.

A ZnO resistive electrical buffer layer is formed on the CdS layer, and serves as an electrical barrier against processing defects that allow the top contact to form a shunt pathway with the back contact. The top and final layer deposited on a thin film solar cell, with the exception of a metal grid and any antireflective coating, is a transparent conductive oxide (TCO) electrode, such as ZnO:Al (AZO), as the top (light receiving) electrical contact. The electrode links the electrical circuit between the top of the device and a metalized grid which is typically opaque, and, therefore, must occupy as small a foot print as possible on the top surface. A TCO electrode layer is necessary because thin n-side layer semiconductors do not provide a continuous pathway that permits collection of the photogenerated electrons at the metal grids. Typical, metal lines of the grid are separated by about 2 mm, as illustrated in FIG. 1.

Progress in CIGS device efficiency requires minimizing all optical losses and, therefore maximizes the available optical energy for photogeneration. The first site of loss is in the transparent conducting oxide (TCO) electrical contact layer. All light that reaches the active layers of the device has to pass through the TCO electrode and all photogenerated current uses the TCO electrode as an electrical transport pathway. Hence, efficiency improvements in the structure of the TCO electrode have the potential to significantly enhance the efficiency of a thin film solar cell.

### SUMMARY OF THE INVENTION

An embodiment of the invention is directed to a graded transparent conductive oxide electrode (G-TCO). The G-TCO electrode is a graded layer of a transparent conductive oxide where the thickness of the graded layer smoothly increases from a distal end to a proximal end where current is collected by a metal grid of a thin film solar cell. The distance from the distal end to the proximal end is 0.5 mm or more, where the thickness of the distal end can be less than 10 nm and the thickness of the proximal end can be up to about 1,000 nm. The average thickness can be one that is calculated as optimal for a given TCO and length from the proximal to distal ends of the electrode.

In an embodiment of the invention, a thin film photovoltaic cell can be constructed using the G-TCO. The efficiency, V_{oc} and fill factor of the cell is improved over that of an equivalent cell that uses a flat TCO electrode.

An embodiment of the invention is directed to a method of preparing a graded transparent conductive oxide electrode (G-TCO) electrode where a mask is suspended over a substrate but does not contact the substrate and the opening in the mask is situated at the proximal end of the electrode that is formed when a G-TCO is deposited by sputtering or an equivalent technique. The substrate can be a thin film photovoltaic cell absent its top electrode where upon deposition of the G-TCO and subsequent deposition of a metal grid, an optional antireflective layer, and/or other optional layer the construction of a photovoltaic cell, or an ensemble of cells is generated.

### BRIEF DESCRIPTION OF DRAWINGS

FIG. 1 is a drawing showing the structure of a state of the art GIGS device and the structure of the layers commonly employed.

FIG. 2 is a graph of the relationship between TCO sheet resistance and optical transmission with thickness.

FIG. 3 shows a schematic diagram of a TCO layer's transfer of photogenerated electric current from a CIGS surface to a metal collection grid where there is an accumulation of current densities as one proceeds from the portion that is distal to the portion that is proximal to the metal contact edge.

FIG. 4 is a plot of the percent transmission over a portion of the electromagnetic spectrum at an optimal thickness of 430 nm for Mg(10%)Zn(90%)O:Sc deposited on bare Corning (soda-lime) glass that displays a resistance of 0.000516 Ω-cm.

FIG. 5 shows plots of the max power points of a 1999 NREL champion cell, where the solid line is the rigorously calculated value for power loss versus thicknesses and the dashed line is calculated using a simplified method with 1 mm contact spacing.

FIG. 6 is a schematic illustration of a traditional flat TCO electrode's inefficiency to carry the current over an optimally thick layer.

FIG. 7 displays a schematic illustration of a graded transparent conductive oxide layer, according to an embodiment of the invention.

FIG. 8 shows plots of the max power points of a 1999 NREL champion cell, where the solid line is the rigorously calculated value for power loss versus thicknesses and the dashed line is calculated using a simplified method with 1 mm contact spacing for a flat TCO electrode (top) and for a G-TCO electrode, according to an embodiment of the invention.

FIG. 9 shows a cross-section of the deposition of a sputtered G-TCO electrode through a mask suspended above the surface for the sputtering deposition, according to an embodiment of the invention.

FIG. 10 shows a sputtered G-TCO electrode top surface of ZnO:Al where the gradient of the G-TCO, according to an embodiment of the invention, is apparent as quarter-wavelength interference contour grading lines from a 532 nm illumination.

FIG. 11 shows a cross-section view of a G-TCO electrode, according to an embodiment of the invention, superimposed on a flat TCO electrode of equal cross-section area, with the positions for a four point probe used for the measurement of sheet resistance on the G-TCO electrode.

FIG. 12 shows a diagram for dimensions and spacings of the contacts for a partially fabricated CIGS devices sheet with a CdS top surface used for fabrication of exemplary photovoltaic devices.

FIG. 13 shows a diagram illustrating the dimensions and orientation of the partially fabricated CIGS device during sputtering.

FIG. 14 is a pair of JV plots for CIGS photovoltaic cells with flat TCO or G-TCO electrodes, according to an embodiment of the invention, where the curves of square symbols indicate flat TCO electrodes and diamonds indicate G-TCO electrodes.

### DETAILED DISCLOSURE

Embodiments of the invention are directed to graded-transparent conducting oxide (G-TCO) electrical contact layer, an electrode, solar cells comprising the G-TCO electrode, and methods for its fabrication. The graded structure of the G-TCO electrode allows retention of desirable electrical properties with the minimization of optical losses that affect the overall efficiency of the TCO and the photovoltaic cell on which it is employed.

Overall TCO electrode performance, by nature of the materials, results from its electrical conductivity performance and its optical performance. There are two electrical properties that describe the performance of TCO contact layers, such as ZnO:Al layers: the bulk electrical conductivity, σ; and the optical adsorption coefficient, α(λ), which varies depending on the wavelength of light, λ. The absolute optical adsorption, A, and absolute sheet resistance, Rs, are the products of the materials bulk coefficients and the film thickness, t:

$$A = α t$$

$${R}_{s} = \frac{1}{σ t} .$$

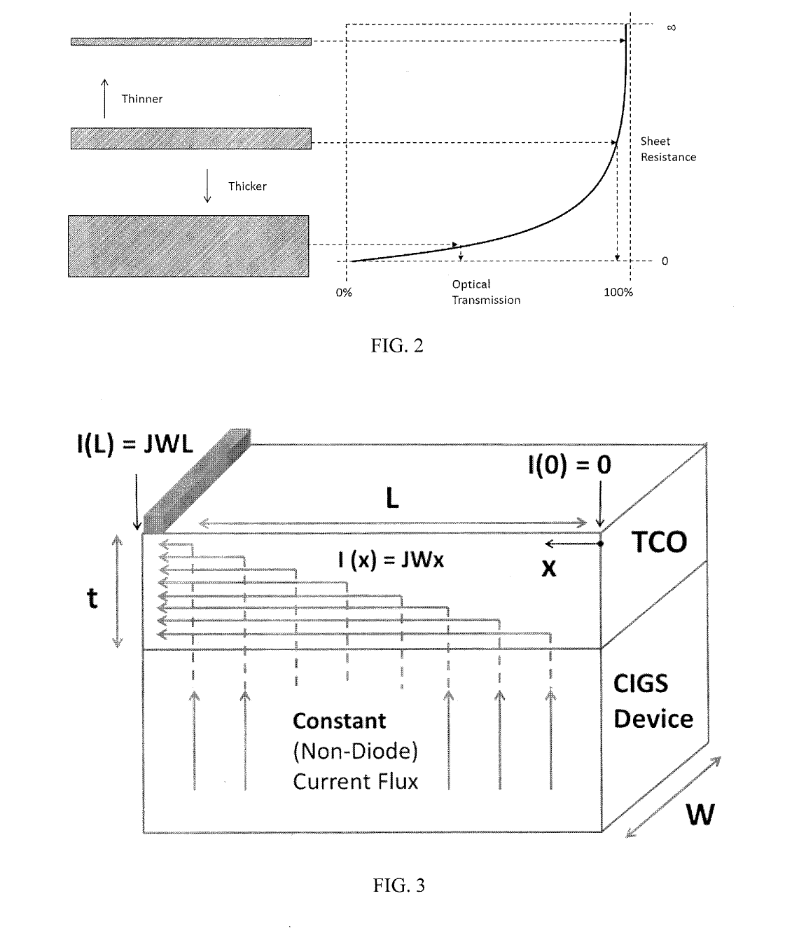

TCO film performance is best when values of A and Rₛ are as low as possible. However, as illustrated in FIG. 2, due to the inverse relationship of A and Rₛ optimization is not so straightforward for any given material.

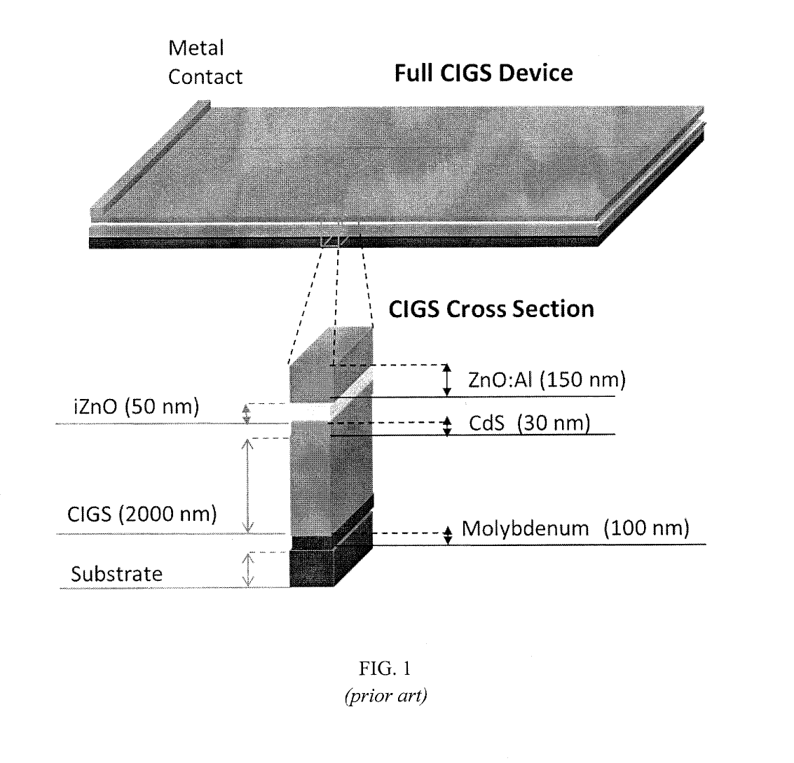

TCO electrodes, such as ZnO:Al, transfer photogenerated electric current from the CIGS surface to the metal collection grid as shown in FIG. 1, with the accumulation of higher densities as current proceeds from the center to the cell, a distal end, to the cell's contact edge at the metal collector, a proximal end, as illustrated in FIG. 3. The power loss due to electric resistance (E_{L}) can be described with a 2D resistance model, as presented in Koishiyev et al. Sol. Energy Mater. Sol. Cells, 2009, 93, 350-4, as:

$${E}_{L} = {\int }_{0}^{L} {( JWx )}^{2} \frac{ρ}{Wt} d x = \frac{1}{3} \frac{{J}^{2} {L}^{3} W ρ}{t} ,$$

where J is the max power point current.

The power loss due to optical absorption loss (O_{L}) is calculated by integration of the absorption loss (1−T(λ)−R(λ)) weighted by thermalization (Cₜₕₑᵣₘ (λ) and the quantum efficiency (C_{QE}(λ)) and is given as:

$$〈 {T}^{*} 〉 = \frac{{\int }_{200 nm}^{1000 nm} {C}_{QE} ( λ ) {C}_{Therm} ( λ ) ⌈ T ( λ ) + R ( λ ) ⌉ {E}_{AM 1.5} ( λ ) d λ}{{\int }_{280 nm}^{1000 nm} {C}_{QE} {C}_{Therm} {E}_{AM 1.5} ( λ ) d λ} ,$$

where <T*> is equivalently the fraction of current lost at the maximum point. The optical loss can be calculated from the maximum power point data:

O_{L}=V*(J*(1−<T*>)).

A TCO displays a total loss that is minimized by determining optimal TCO thickness in the following manner. <T*> is linearized as a function of the film thickness by:

<T*>=t*<α₁>

where α₁ is an integral-lumped optical absorption term.
The power loss is given by the equation:

P_{L}(t)=₃¹ρJ²L²t⁻¹|α₁JVt,

where the optimal film thickness is found by the local minimum found by the derivative:

$$\frac{d {P}_{L} ( t )}{d t} = 0 = - \frac{1}{3} ρ {J}^{2} {L}^{2} {t}^{- 2} + {α}_{I} J V$$

$$to yield \text{:}$$

$${t}_{opt} = L \sqrt{\frac{1}{3} \frac{ρ J}{{α}_{I} V}} ;$$

the optimal thickness is dependent on the distance from the proximal end at a metal grid contact.

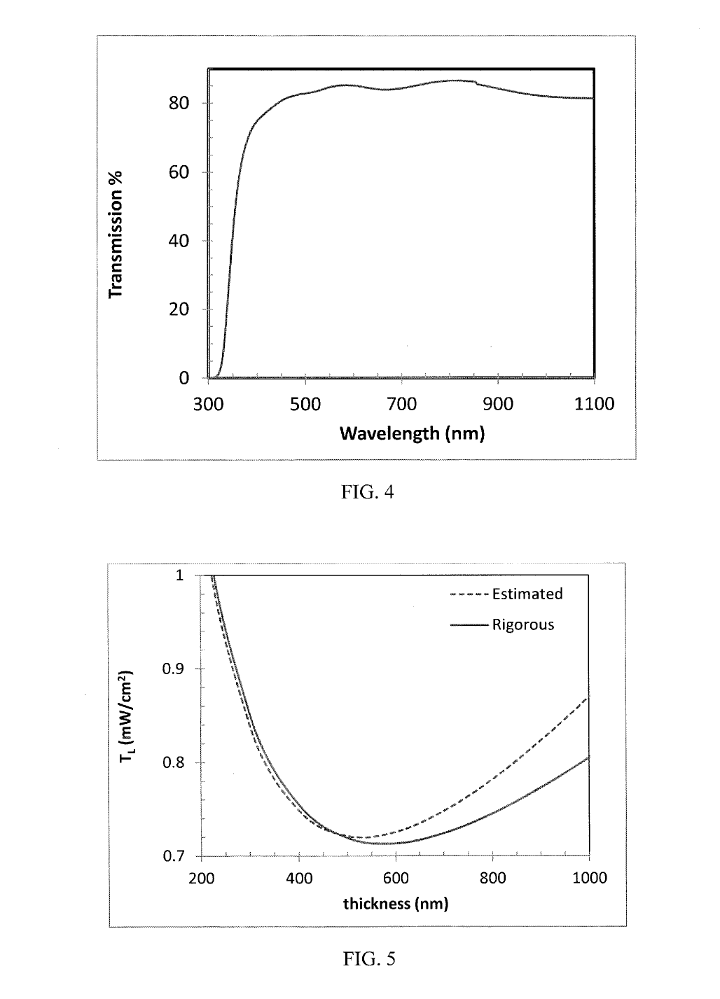

Using the absorption data from FIG. 4 and values for the maximum power point of a 1999 NREL champion cell (19 mW/cm² at 1 sun AM1.5) from Contreras et al. Prog. Photovolt. Res. Appl., 1999 7, 311-6, the calculated curves of FIG. 5 are constructed where the solid line is generated by the equations above for a multiplicity of thicknesses, and the dashed line employs some simplifications that result in error of less than 10% at greater thicknesses, with the length L set at 1 mm. There is a good fit of the simplified method around the optimal film thickness. At higher film thicknesses there is a greater discrepancy in values between the simplified and rigorous methods due to the error in linearizing the optical loss calculation. The optimal film thickness of 530 nm, predicted for tₒₚₜ, matches the plotted calculation of the trend. The optimal film thickness from the rigorous method of 580 nm deviates by the small difference in TCO power loss in the thickness range of 500 to 600 nm.

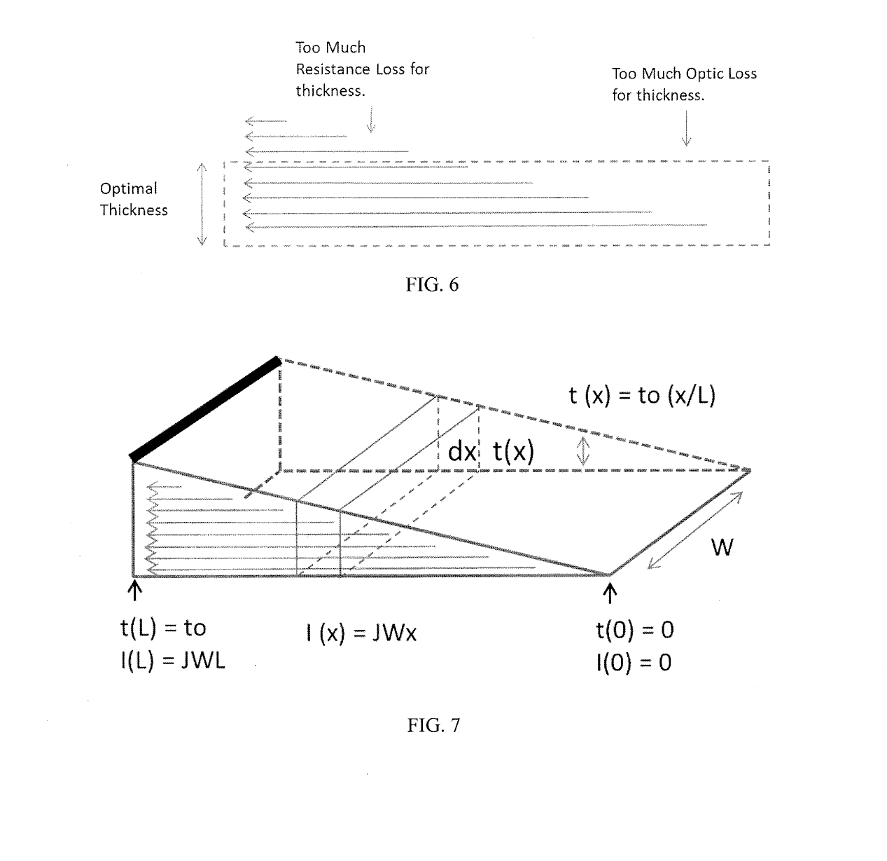

If the TCO is thicker than that required for the amount of current it must support, there is unnecessary optic loss, as indicated on the right, distal end, of an electrode in FIG. 6. If the TCO is too thin, as shown on FIG. 6 near the metal line of the grid to the left, the proximal end, there is unnecessary electric loss. The graded transparent conducting oxide (G-TCO) layer, according to an embodiment of the invention, matches the electrode's thickness to the load that must be carried by having a triangularly-shaped gradient structure, where its thickness is proportional to the local current density from the center, distal end, to the metal grid contact edge, the proximal end, as illustrated in FIG. 7. Analytical losses for the G-TCO are:

$${E}_{L} = \begin{matrix}{x}^{{J}^{2} {L}^{2} ρ} \\ t\end{matrix} ,$$

where x=⅓ for flat and ¼ for graded, t is the constant thickness of a flat TCO and the average thickness for the G-TCO; and

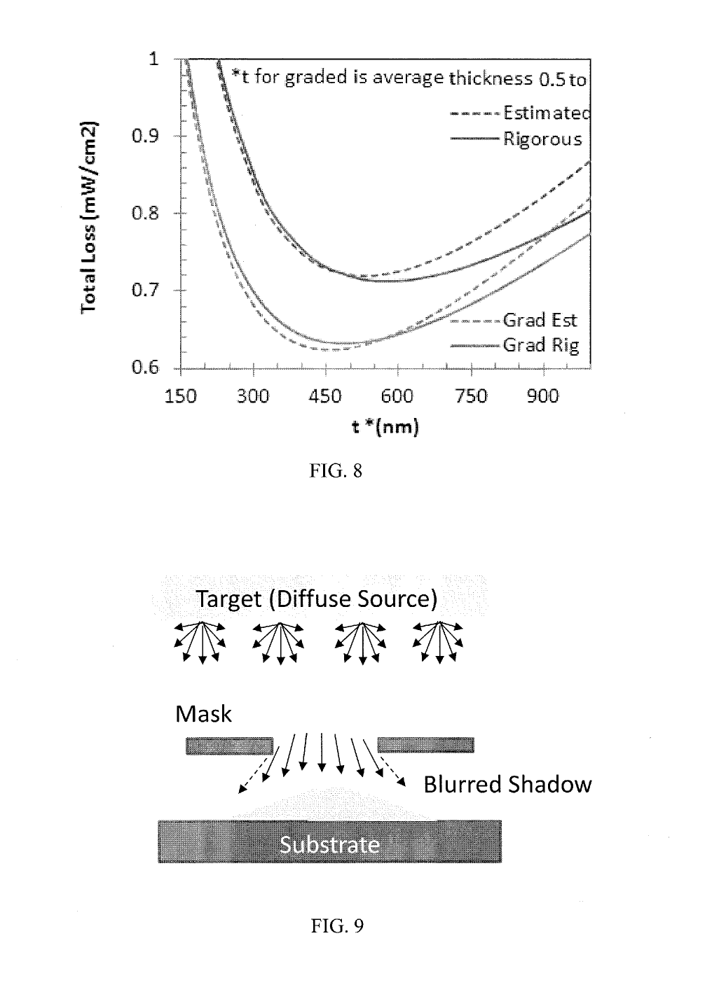

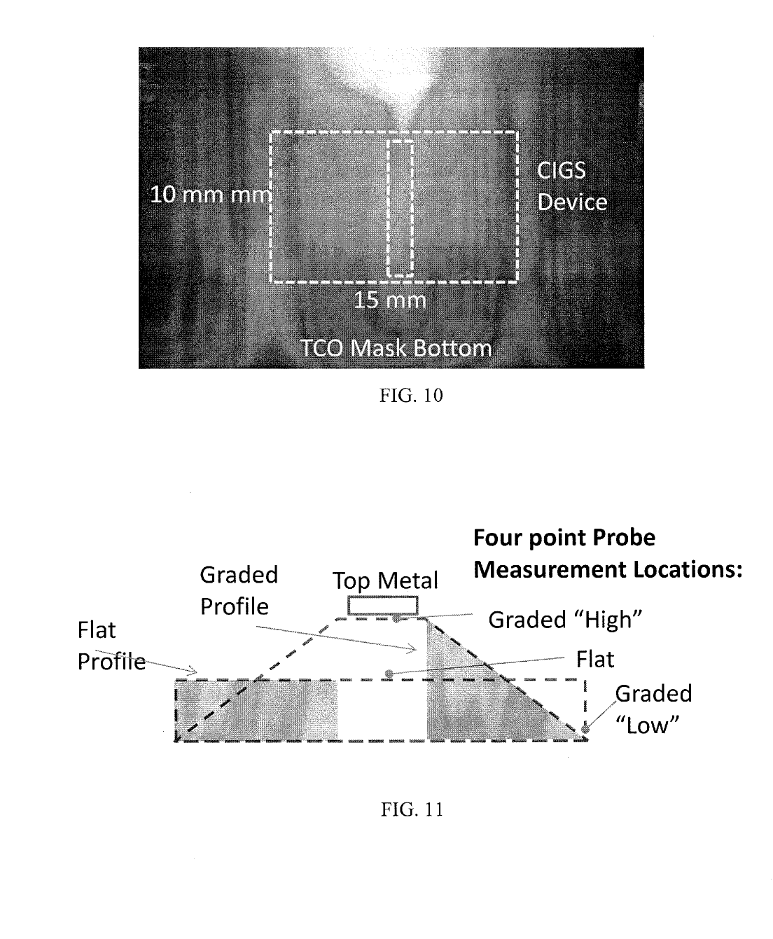

O_{L}=yα₁tVJ,

where y=1 for flat and 1 for graded. As can be seen in FIG. 8, the G-TCO has less than about 15% loss than does a flat TCO layer. The results of the simplified calculations assume that the flat and G-TCO have equal t.

Although all exemplary embodiments employ a CIGS cell as the thin film active layer and a ZnO:Al TCO as the top electrode, the invention is not so limited,. In addition to CIGS, the cell can use cadmium telluride (CdTe), a-Si, dyes (in a dye-sensitized solar cell (DSC)) and other organic absorbers (in an organic solar cell). In addition to ZnO:Al (AZO), the TCO used for the G-TCO electrodes, according to embodiments of the invention, include, but are not limited to: Ga-doped ZnO (GZO); ZnO—In₂O₃—SnO₂; (Zn—In—Sn—O) multi-component oxides; ITO; Zn₂In₂O₅; Zn₃In₂O₆; ZnO—In₂O₃; In₄Sn₃O₁₂; In₂O₃—SnO₂; CdIn₂O₄; CdO—In₂O₃; Cd₂SnO₄; CdSnO₃; CdO—SnO₂; Zn₂SnO₄; ZnSnO₃; ZnO doped with B, In, Y, Sc, V, Si, Ge, Ti, Zr, or Hf; CdO doped with In or Sn; In₂O₃ doped with Sn, Ge, Mo, Ti, Zr, Hf, Nb, Ta, W, or Te; or SnO₂ doped with Sb, As, Nb, or Ta.

In an embodiment of the invention, a method of forming a G-TCO electrode includes the sputtering of a TCO on a surface of a layer in the thin film solar cell, for example, on a resistive electrical buffer layer, using a mask, where the grading is effectively formed in the blurred diffuse shadow of a mask that is not in intimate contact with the surface upon which the G-TCO is formed, as illustrated in FIG. 9. In addition to sputtering, any line of sight solid deposit technique can be used.

The G-TCO electrodes can benefit an array of photovoltaic cells by permitting the lines of the metal grid to be spaced farther apart than the traditional flat TCO electrode arrays. The reduction of the metal grid increases the surface for absorption of light and its conversion to electrical current.

### METHODS AND MATERIALS

A G-TCO electrode of ZnO:Al that was prepared using the method, according to an embodiment of the invention, is shown under illumination by 532 nm light. The image reveals contour grading lines due to quarter-wavelength interference, according to the equation:

$$F ( t , λ ) = sin ( 2 π n ( λ ) ( \frac{t}{λ} ) ) - 1$$

where each contour, each light to dark to light transition, reflects a thickness difference of 140 nm. The G-TCO's cross-section profiles is illustrated in FIG. 11 relative to a flat TCO of the same average thickness, A1=A2, for the flat and G-TCO, respectively. The positions for 4 point probe measurements are indicated as high and low.

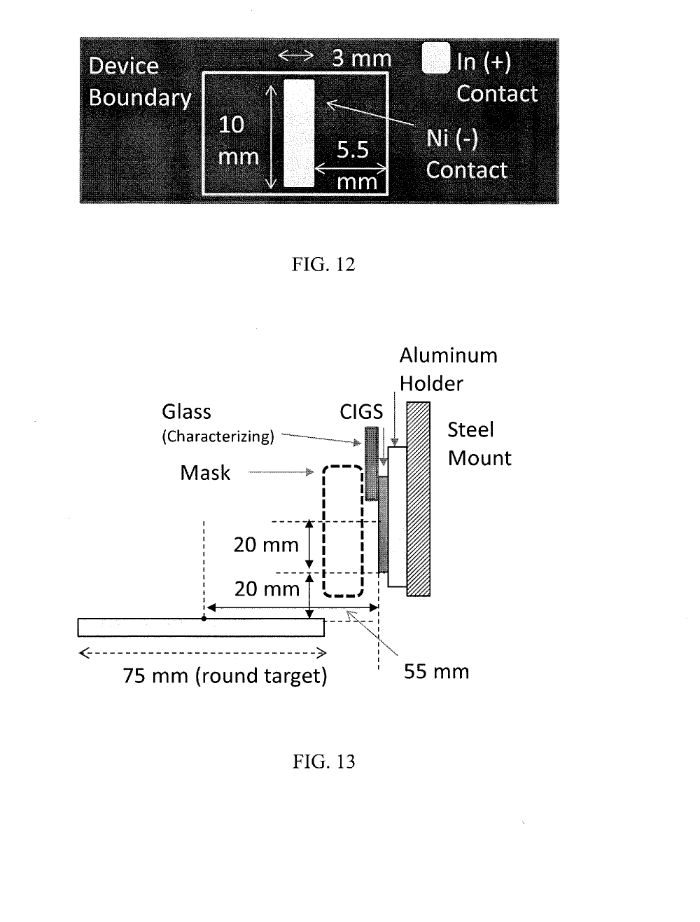

Partially fabricated CIGS devices, as illustrated in FIG. 12, which are terminated after the CdS deposition, were obtained from an industrial source, where the dimensions of features on the device are indicated in FIG. 12. The partially fabricated device was oriented during sputtering as shown in FIG. 13, with the distances indicated in the figure. The sputtering conditions are given in Table 1, below.

TABLE 1
Sputtering Conditions

| | |
|---|---|
| Material | Zn:Al @ 2.4 mol % |
| Power | 60 Watts |
| Time | 30 minutes Flat, 1 hour Graded (5 |
| | minutes for resistive ZnO) |
| Pressure | 1 mTorr |
| Oxygen | 0.13 to 0.15 mTorr (conductive), 0.30 (resistive) |
| Substrate | Soda-lime glass, CIGS |
| Substrate | 22 to 36° C. (by TC on the steel mount) |
| Temperature | |

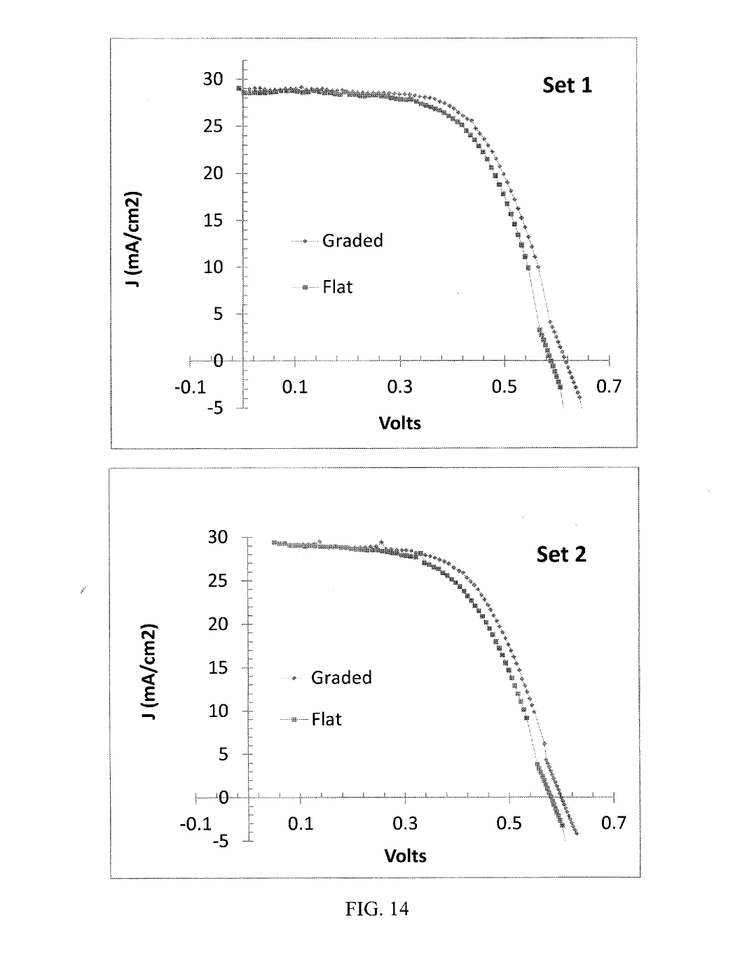

The JV results of otherwise equivalent flat TCO and G-TCO devices are shown in FIG. 14 enhancement of the graded TCO versus the flat for two tandem experiments and properties are tabulated below in Table 2 where solar cell performance was obtained from power measurements under the terrestrial light standard: Air Mass 1.5 (AM1.5) taken with an in-house built probe station and Labview parameter analyzer setup. The G-TCO comprising CIGS solar cells display efficiency improvements of 0.8%, Voc improvements by 25 mV, and fill factor improvements of 0.02.

TABLE 2
Parameters measured for flat TCO
and G-TCO comprising CIGS cells.

| | | Rs High | Rs Low | Voc | Jsc | | |
|---|---|---|---|---|---|---|---|
| | | (W/sq) | (W/sq) | (V) | (mA/cm²) | F.F. | Eff. % |
| Set 1 | Flat | 18.1 | | 0.58 | 29.4 | 0.579 | 9.87 |
| | Graded | 7.02 | 50.3 | 0.599 | 29.1 | 0.614 | 10.7 |
| Set 2 | Flat | 10.2 | | 0.59 | 29.0 | 0.614 | 10.5 |
| | Graded | 4.99 | 27.2 | 0.616 | 29.0 | 0.627 | 11.2 |

All publications referred to or cited herein are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

We claim:

1. A graded transparent conductive oxide electrode (G-TCO), comprising a graded layer of a transparent conductive oxide, wherein the thickness of the graded layer smoothly increases from a distal end to a proximal end, wherein current is drawn from the proximal end of the electrode.

2. The G-TCO of claim 1, wherein the transparent conductive oxide is ZnO:Al (AZO), Ga-doped ZnO (GZO); ZnO—In₂O₃—SnO₂ (Zn—In—Sn—O), ITO, Zn₂In₂O₅, Zn₃In₂O₆, ZnO—In₂O₃, In₄Sn₃O₁₂ In₂O₃—SnO₂, CdIn₂O₄, CdO—In₂O₃, Cd₂SnO₄, CdSnO₃, CdO—SnO₂, Zn₂SnO₄, ZnSnO₃, ZnO doped with B, ZnO doped with In, ZnO doped with Y, ZnO doped with Sc, ZnO doped with V, ZnO doped with Si, ZnO doped with Ge, ZnO doped with Ti, ZnO doped with Zr, ZnO doped with Hf, CdO doped with In, CdO doped with Sn; In₂O₃ doped with Sn, In₂O₃ doped with Ge, In₂O₃ doped with Mo, In₂O₃ doped with Ti, In₂O₃ doped with Zr, In₂O₃ doped with Hf, In₂O₃ doped with Nb, In₂O₃ doped with Ta, In₂O₃ doped with W, In₂O₃ doped with Te; SnO₂ doped with Sb, SnO₂ doped with As, SnO₂ doped with Nb, or SnO₂ doped with Ta.

3. The G-TCO electrode of claim 1, wherein the distance from the distal end to the proximal end is 0.5 mm or more.

4. The G-TCO electrode of claim 1, wherein the distal end has a thickness less than 10 nm.

5. The G-TCO electrode of claim 1, wherein the proximal end has a thickness less than 1000 nm.

6. A thin film photovoltaic cell, comprising a G-TCO electrode according to claim 1.

7. The thin film photovoltaic cell according to claim 6, comprising Zn:Al as the transparent conductive oxide.

8. The thin film photovoltaic cell according to claim 6, further comprising an active layer comprising copper indium gallium diselenide (CIGS), cadmium telluride (CdTe), a-Si, a dye, or an organic material.

9. The thin film photovoltaic cell according to claim 6, further comprising a metal current collector, wherein a portion of the metal current collector is attached to the proximal end of the G-TCO electrode.

10. A method of preparing a graded transparent conductive oxide electrode (G-TCO) electrode according to claim 1, comprising:
providing a substrate;
suspending a mask above the surface of the substrate, wherein the mask is not in contact with the surface; and
depositing the G-TCO by sputtering or an equivalent line of sight solid deposition method a transparent conductive oxide through the suspended mask, wherein proximal ends of the G-TCO electrode are formed at the opening of the mask and the distal end of the G-TCO electrode is formed under a solid portion of the mask.

11. A method of claim 10, wherein the substrate is a thin film photovoltaic cell absent a top electrode.
